(19) United States
(12) Patent Application Publication
(10) Pub. No.: US 2025/0257993 A1
(43) Pub. Date: Aug. 14, 2025

(54) OPTICAL MEASUREMENT DEVICE FOR DIE BONDING ALIGNMENT

(71) Applicant: SANSUNG ELECTRONICS CO., LTD., Suwon-si (KR)

(72) Inventors: Seunghoon HAN, Suwon-si (KR); Heejin Choi, Suwon-si (KR); Kyuhwan Choi, Suwon-si (KR)

(73) Assignee: SAMSUNG ELECTRONICS CO., LTD., Suwon-si (KR)

(21) Appl. No.: 19/045,960

(22) Filed: Feb. 5, 2025

(30) Foreign Application Priority Data
Feb. 8, 2024 (KR) 10-2024-0019830

(51) Int. Cl. G01B 11/27

(52) U.S. Cl. CPC G01B 11/272

(57) ABSTRACT

An optical measurement device includes: a first align mark including at least one transmissive diffractive element; a second align mark apart from the first align mark in a first direction and including at least one reflective diffractive element; a beam splitter configured to reflect incident light in a direction toward the first align mark and transmit light from the first align mark; a focusing lens on a path of the light that passes through the beam splitter; and at least one image sensor configured to sense the light after the light passes through the focusing lens.

### CROSS-REFERENCE TO RELATED APPLICATION

This application is based on and claims priority under 35 U.S.C. § 119 to Korean Patent Application No. 10-2024-0019830, filed on Feb. 8, 2024, in the Korean Intellectual Property Office, the disclosure of which is incorporated by reference herein in its entirety.

### BACKGROUND

### 1. Field

Embodiments of the present disclosure relate to an optical measurement device for die bond alignment.

### 2. Description of the Related Art

The degree of integration of various integrated circuit devices, including memories, driver integrated circuits (ICs), logic devices, and image sensors, is increasing gradually, and accordingly, the size of electronic devices included therein is also reduced.

Additionally, with the development of system semiconductors, the size of chiplets and dies is gradually increasing in 2.5-dimensional (2.5D) and 3D packages, artificial intelligence (AI), and high-performance computing (HPC) semiconductor systems.

Electronic devices formed on different substrates may be packaged into one package by using an align mark provided on each substrate. A measurement method for satisfying the reduction in optical resolution required according to a decrease in a bonding pad pitch and an increase in a die size according to the development of system semiconductors is being researched.

### SUMMARY

According to embodiments of the present disclosure, an optical measurement device is provided for increasing the precision of die bonding alignment when manufacturing an electronic device.

According to embodiments of the present disclosure, an optical measurement device is provided and includes: a first align mark including at least one transmissive diffractive element; a second align mark apart from the first align mark in a first direction and including at least one reflective diffractive element; a beam splitter configured to reflect incident light in a direction toward the first align mark and transmit light from the first align mark; a focusing lens on a path of the light that passes through the beam splitter; and at least one image sensor configured to sense the light after the light passes through the focusing lens.

Additional aspects will be set forth in part in the description which follows and, in part, will be apparent from the description, or may be learned by practice of the presented embodiments of the disclosure.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 illustrates a schematic structure of an optical measurement device according to an embodiment;

FIG. 2A illustrates an example of structure of a first align mark provided in an optical measurement device according to an embodiment;

FIG. 2B illustrates an example of structure of a second align mark provided in an optical measurement device according to an embodiment;

FIG. 3A illustrates an example of a shape of a nanostructure that may be provided in first and second align marks of an optical measurement device according to an embodiment;

FIG. 3B illustrates an example of a shape of a nanostructure that may be provided in first and second align marks of an optical measurement device according to an embodiment;

FIG. 4 conceptually illustrates that, when using an optical measurement device according to an embodiment, arrangement positions of dies to be aligned vary depending on a size of the dies;

FIG. 5 illustrates a schematic structure of an optical measurement device according to another embodiment;

FIG. 6A illustrates an example of a change in polarization of light on a light path within the optical measurement device of FIG. 5;

FIG. 6B illustrates an example of a change in polarization of light on a light path within the optical measurement device of FIG. 5;

FIG. 7A illustrates an example of a shape of a nanostructure that may be provided in first and second align marks of the optical measurement device of FIG. 5;

FIG. 7B illustrates an example of a shape of a nanostructure that may be provided in first and second align marks of the optical measurement device of FIG. 5;

FIG. 8 illustrates a schematic structure of an optical measurement device according to an embodiment;

FIG. 9 illustrates a schematic structure of an optical measurement device according to an embodiment;

FIG. 10 illustrates a schematic structure of an optical measurement device according to an embodiment;

FIG. 11 illustrates a schematic structure of an optical measurement device according to an embodiment; and

FIG. 12 illustrates a schematic structure of an optical measurement device according to an embodiment.

### DETAILED DESCRIPTION

Reference will now be made in detail to non-limiting examples of the present disclosure, with reference to the drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects. As used herein, the term “and/or” includes any and all combinations of one or more of the associated listed items. Expressions such as “at least one of,” when preceding a list of elements, modify the entire list of elements and do not modify the individual elements of the list.

In the drawings, the same reference numerals refer to the same components, and the size of each component in the drawings may be exaggerated for clarity and convenience of explanation.

It will also be understood that when an element is referred to as being “on” or “above” another element, the element may be in direct contact with the other element or other intervening elements may be present.

Terms such as “first,” “second,” etc. may be used to describe various components, but are used only for the purpose of distinguishing one component from another component. These terms do not limit the difference in material or structure of the constituent elements.

The singular forms include the plural forms unless the context clearly indicates otherwise. It should be understood that, when a part “comprises” or “includes” an element in the specification, unless otherwise defined, other elements are not excluded from the part and the part may further include other elements.

In addition, terms such as “ . . . unit”, “module”, or the like refer to units that perform at least one function or operation, and the units may be implemented as hardware or software or as a combination of hardware and software.

The use of the terms “a” and “an” and “the” and similar referents in the context of describing the disclosure are to be construed to cover both the singular and the plural.

The steps comprising a method may be performed in any suitable order unless explicitly stated that they must be performed in the order described. In addition, the use of all exemplary terms (e.g., etc.) is simply for explaining example embodiments of the present discourse.

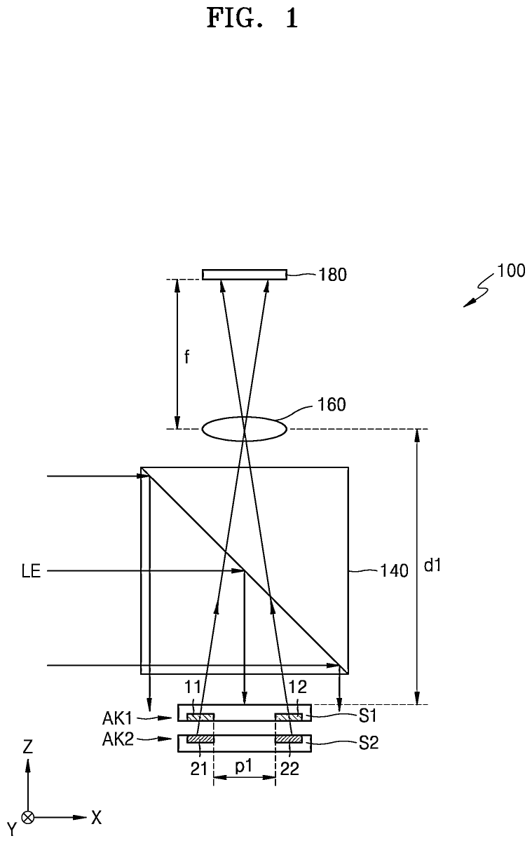

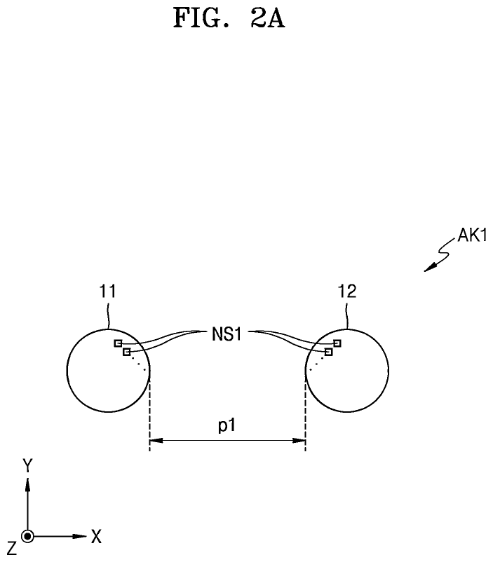

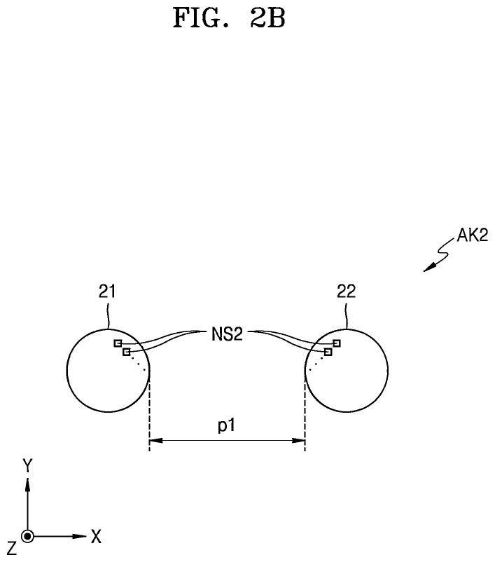

FIG. 1 illustrates a schematic structure of an optical measurement device according to an embodiment, and FIGS. 2A and 2B illustrate examples of structures of a first align mark and a second align mark provided in an optical measurement device according to an embodiment, respectively.

An optical measurement device 100 is a device that measures whether alignment is properly performed during die bonding. A die may refer to a chip, chiplet, wafer, circuit board, etc., that includes a metal pattern, semiconductor pattern, insulating pattern, or various devices to be bonded or packaged. Hereinafter, a die will simply be referred to as a substrate or die.

The optical measurement device 100 may include a first align mark AK1 including a transmissive diffractive element, a second align mark AK2 including a reflective diffractive element, a beam splitter 140, a focusing lens 160, and an image sensor 180.

The first align mark AK1 may be provided on a first substrate S1, and the second align mark AK2 may be provided on a second substrate S2. According to embodiments, the first substrate S1 and the second substrate S2 may include device layers including a metal pattern, a semiconductor pattern, or an insulating pattern.

The first align mark AK1 and the second align mark AK2 are used to accurately combine elements manufactured on two separate substrates (e.g., the first substrate S1 and the second substrate S2). The first align mark AK1 and the second align mark AK2 are arranged apart from each other in a first direction (Z direction). The first align mark AK1 and the second align mark AK2 may be arranged to face each other. The first align mark AK1 and the second align mark AK2 may not be aligned when viewed in the first direction (Z direction). For example, the first align mark AK1 and the second align mark AK2 may be arranged apart from each other not only in the first direction (Z direction) but also in a second direction (X) perpendicular to the first direction (Z direction) or also in a third direction (Y direction).

A beam pattern due to the first align mark AK1 and the second align mark AK2 varies depending on an alignment state of the first substrate S1 and the second substrate S2, and the beam pattern may be detected by the image sensor 180.

The first align mark AK1 may include a first transmissive diffractive element 11 and a second transmissive diffractive element 12. The first transmissive diffractive element 11 and the second transmissive diffractive element 12 may be arranged apart from each other in, for example, the second direction (X direction) perpendicular to the first direction. A spacing between the first transmissive diffractive element 11 and the second transmissive diffractive element 12 may be a spacing p1.

The second align mark AK2 may include a first reflective diffractive element 21 and a second reflective diffractive element 22. The first reflective diffractive element 21 and the second reflective diffractive element 22 may be arranged to face the first transmissive diffractive element 11 and the second transmissive diffractive element 12, respectively. The first reflective diffractive element 21 and the second reflective diffractive element 22 may be arranged apart from each other in, for example, the second direction (X direction) perpendicular to the first direction. A spacing between the first reflective diffractive element 21 and the second reflective diffractive element 22 may be a spacing p1.

Here, the spacing between the first reflective diffractive element 21 and the second reflective diffractive element 22 and the spacing between the first transmissive diffractive element 11 and the second transmissive diffractive element 12 are shown to be both the spacing p1. However, this is an example and the spacings are not limited thereto. The spacings may be different from each other in a range that may provide a standard for determining alignment. For example, in a state where the first substrate S1 and the second substrate S2 are properly aligned, the two spacings may be different in a range in which a light path may be formed, through which light that has passed through the first transmissive diffractive element 11 and enters the first reflective diffractive element 21 is reflected by the first reflective diffractive element 21 and then proceeds again toward the first transmissive diffractive element 11.

The beam splitter 140 may reflect incident light LE in a direction toward the first align mark AK1 and transmit through light from the first align mark AK1. The beam splitter 140 may be a half mirror that transmits a portion of the incident light LE and reflects another portion thereof.

The light reflected from the beam splitter 140 is directed to the first align mark AK1, passes through the first align mark AK1, and is directed to the second align mark AK2. Next, after being reflected from the second align mark AK2, the light passes through the first align mark AK1, enters the beam splitter 140, passes through the beam splitter 140, and proceeds toward the focusing lens 160. That is, the light reflected from the beam splitter 140 sequentially passes through the first transmissive diffractive element 11, the first reflective diffractive element 21, and then the first transmissive diffractive element 11 or through the second transmissive diffractive element 12, the second reflective diffractive element 22, and then the second transmissive diffractive element 12 to be incident on the beam splitter 140, pass through the beam splitter 140, and proceed toward the focusing lens 160.

The light path described above is an example is not limited thereto. For example, the light reflected from the beam splitter 140 may not pass through the first align mark AK1, but may instead enter the second align mark AK2, be reflected from the second align mark AK2, and then pass through the first align mark AK1 to be incident on the beam splitter 140 and transmit through the beam splitter 140. Alternatively, the light reflected from the beam splitter 140 may pass through the first align mark AK1, enter the second align mark AK2, be reflected from the second align mark AK2, and then enter the beam splitter 140 through a path that does not pass through the first align mark AK1, and pass through the beam splitter 140.

The focusing lens 160 may be arranged between the image sensor 180 and the beam splitter 140, and the image sensor 180 may be arranged at position of a focal length f of the focusing lens 160.

In other embodiments, the position of the image sensor 180 may be different. For example, a magnifying optical system such as a relay lens may be located between the image sensor 180 and the focusing lens 160. In this case, the magnifying optical system may be arranged at the position of the focal length f of the focusing lens 160.

A distance d1 between the focusing lens 160 and the first substrate S1 may be determined such that, while the first substrate S1 and the second substrate S2 are aligned with each other, light that has passed through the first align mark AK1 and the second align mark AK2 is directed toward a center of the focusing lens 160. However, this is an example, and the distance d1 and the spacing p1 between the first transmissive diffractive element 11 and the second transmissive diffractive element 12 may be determined based on other standards.

The optical measurement device 100 of an embodiment forms infinite-focused optics and, therefore, there is little difference in measurement precision depending on the die size.

The first align mark AK1 and the second align mark AK2 may be elements based on (e.g., formed of) nanostructures.

Referring to FIG. 2A, the first transmissive diffractive element 11 and the second transmissive diffractive element 12 included in the first align mark AK1 may each include a plurality of first nanostructures NS1.

The shape and arrangement of the first nanostructures NS1 may be determined such that the first align mark AK1 operates as a transmissive diffractive element. The first transmissive diffractive element 11 and the second transmissive diffractive element 12 may be meta-lenses. The first transmissive diffractive element 11 and the second transmissive diffractive element 12 may be meta-deflectors such as, for example, a transmissive meta-deflector. The first transmissive diffractive element 11 and the second transmissive diffractive element 12 may be lenses that also function as deflectors. In this case, the first transmissive diffractive element 11 and the second transmissive diffractive element 12 may have different light deflecting directions and the same refractive power as each other. However, embodiments of the present disclosure are not limited thereto.

Referring to FIG. 2B, the first reflective diffractive element 21 and the second reflective diffractive element 22 included in the second align mark AK2 may each include a plurality of second nanostructures NS2.

The shape and arrangement of the second nanostructures NS2 may be determined such that the second align mark AK2 operates as a reflective diffractive element. The first reflective diffractive element 21 and the second reflective diffractive element 22 may be meta-mirrors. The first reflective diffractive element 21 and the second reflective diffractive element 22 may be meta-deflectors such as, for example, a reflective meta-deflector. The first reflective diffractive element 21 and the second reflective diffractive element 22 may be meta-mirrors or meta-deflectors having refractive power. The first reflective diffractive element 21 and the second reflective diffractive element 22 may be reflective meta-deflectors having refractive power. In this case, directions in which the first reflective diffractive element 21 and the second reflective diffractive element 22 deflect light may be different from each other. However, embodiments of the present disclosure are not limited thereto.

The first nanostructures NS1 and the second nanostructures NS2 each independently have a sub-wavelength shape dimension, that is, a shape dimension smaller than a center wavelength of an operating wavelength band. Arrangement pitches of the first nanostructures NS1 and the second nanostructure NS2 may also be a sub-wavelength, or may be equal to or less than ⅔ of the center wavelength of the operating wavelength band. Heights of the first nanostructure NS1 and the second nanostructure NS2 may range from a sub-wavelength to a wavelength or more.

The first nanostructures NS1 and the second nanostructures NS2 may each independently include a metal or a high refractive index material. The first nanostructures NS1 and the second nanostructures NS2 may include Cu, W, or TIN, or other various metal materials, or, c-Si, p-Si, a-Si, Group III-V compound semiconductors (GaAs, GaP, GaN, etc.), SiC, SiO₂, TiO₂, or SiN.

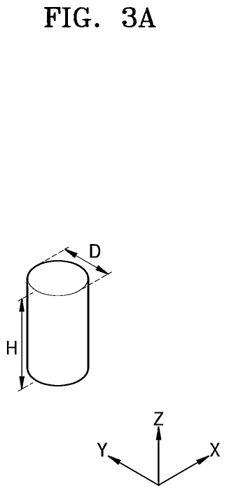

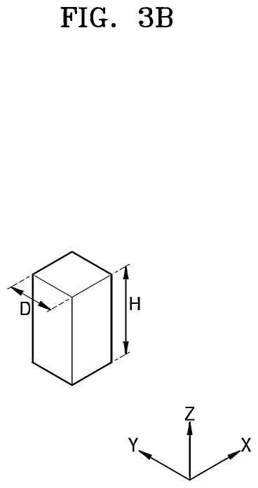

FIGS. 3A and 3B illustrate examples of shapes of nanostructures that may be respectively provided in first and second align marks of an optical measurement device according to an embodiment.

The first nanostructures NS1 and the second nanostructures NS2 may each independently have a cylindrical shape with a diameter of length D and a height of length H as illustrated in FIG. 3A, or a square pillar shape with one side of length D and a height of length H as illustrated in FIG. 3B.

The first nanostructures NS1 may all have the same height, and the length D may be set differently depending on the relative positions of each of the first nanostructures NS1 within the first align mark AK1. As described above, a desired phase profile may be implemented by adjusting the size of the first nanostructures NS1 depending on the position. For example, a cross-sectional size, length D, of each first nanostructure NS1 may be determined such that the first transmissive diffractive element 11 and the second transmissive diffractive element 12 each function as a meta-lens having a desired refractive power and effective diameter or a meta-deflector having a desired directivity. However, the first nanostructures NS1 are not limited to all having the same height of length H. The heights of the first nanostructures NS1 included in the first transmissive diffractive element 11 and the heights of the first nanostructures NS1 included in the second transmissive diffractive element 12 may be different from each other, and the heights of the first nanostructures NS1 may also be different within the first transmissive diffractive element 11 or the second transmissive diffractive element 12.

All of the second nanostructures NS2 may have the same height, and length D may be set differently depending on the relative positions of the second nanostructures NS2 within the second align mark AK2 where each of the second nanostructures NS2 is arranged. As described above, a desired phase profile may be implemented by adjusting the size of the second nanostructures NS2 depending on the relative positions of each of the second nanostructures NS2. For example, a cross-sectional size, length D, of each second nanostructure NS2 may be determined such that the first reflective diffractive element 21 and the second reflective diffractive element 22 may each function as a meta-lens having a desired refractive power and effective diameter or a meta-deflector having a desired directivity.

The nanostructures illustrated in FIGS. 3A and 3B are illustrated as having a cross-sectional shape perpendicular to the first direction (Z direction) and symmetrical with respect to at least two axial directions (X direction, Y direction), but are not limited thereto. For example, nanostructures may have cross-sectional shapes with different lengths in the X direction and the Y direction. These nanostructures may have the same size, and the arrangement angle thereof may be set according to the relative positions thereof within the first align mark AK1 and the second align mark AK2 so as to realize a desired phase profile.

The transmissive diffractive elements and the reflective diffractive elements constituting the first align mark AK1 and the second align mark AK2 are not limited to the form including the illustrated nanostructures. The transmissive diffractive elements and the reflective diffractive elements constituting the first align mark AK1 and the second align mark AK2 may include, for example, various micro-patterns capable of diffracting, reflecting, or scattering light.

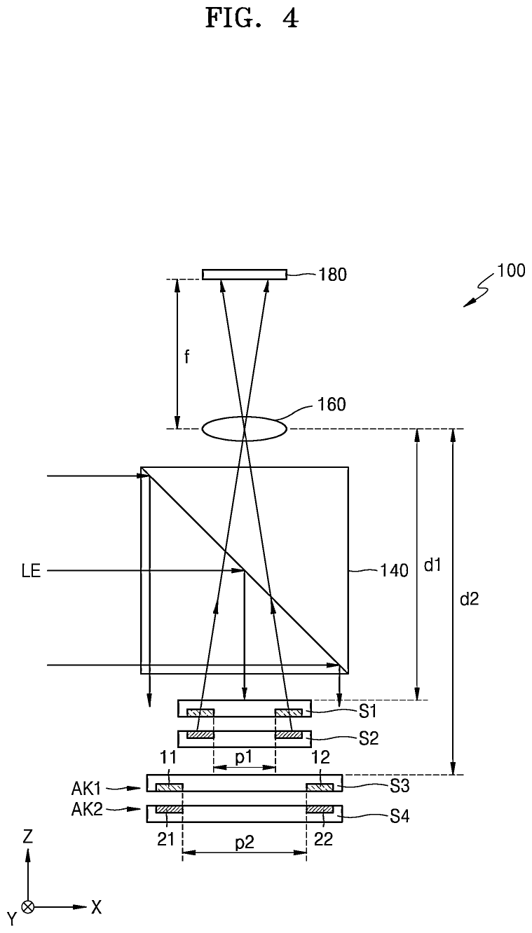

FIG. 4 conceptually illustrates that, when using an optical measurement device according to an embodiment, arrangement positions of dies to be aligned vary depending on a size of the dies.

When aligning a third substrate S3 and a fourth substrate S4 that have different sizes from the first substrate S1 and the second substrate S2, locations at which the third substrate S3 and the fourth substrate S4 are arranged may be different from the locations where the first substrate S1 and the second substrate S2 are arranged.

The third substrate S3 may be larger than the first substrate S1, for example, larger in the X direction. In this case, for alignment measurement, the location where the third substrate S3 is arranged may be different from the location where the first substrate S1 is arranged. That is, a distance d2 between the third substrate S3 and the focusing lens 160 may be different from the distance d1 between the first substrate S1 and the focusing lens 160.

As illustrated, when the third substrate S3 is larger than the first substrate S1, the distance d2 may be larger than the distance d1. Additionally, a spacing p2 between the first transmissive diffractive element 11 and the second transmissive diffractive element 12 provided in the third substrate S3 may also be different from the spacing p1.

The relationship between the distance d2 and the spacing p2 may be almost identical or similar to the relationship between the distance d1 and the spacing p1. For example, d2/p2=d1/p1, or d2/p2=d1/p1. The detailed criteria by which the distance d1, the distance d2, the spacing p1, and the spacing p2 are defined may change to some extent. In the drawing, the spacing p1 or the spacing p2 is indicated as the spacing between the first transmissive diffractive element 11 and the second transmissive diffractive element 12, but may also be defined as a distance between a center of the first transmissive diffractive element 11 and the second transmissive diffractive element 12. the distance d1 and the distance d2 may be defined as a distance from a center of the focusing lens 160 to the first align mark AK1 arranged on the first substrate S1 and a distance from a center of the focusing lens 160 to the first align mark AK1 arranged on the third substrate S3, respectively.

As described above, even if the size of a die increases, the optical measurement device 100 according to the embodiment may measure alignment with the same precision by adjusting the arrangement position of the die.

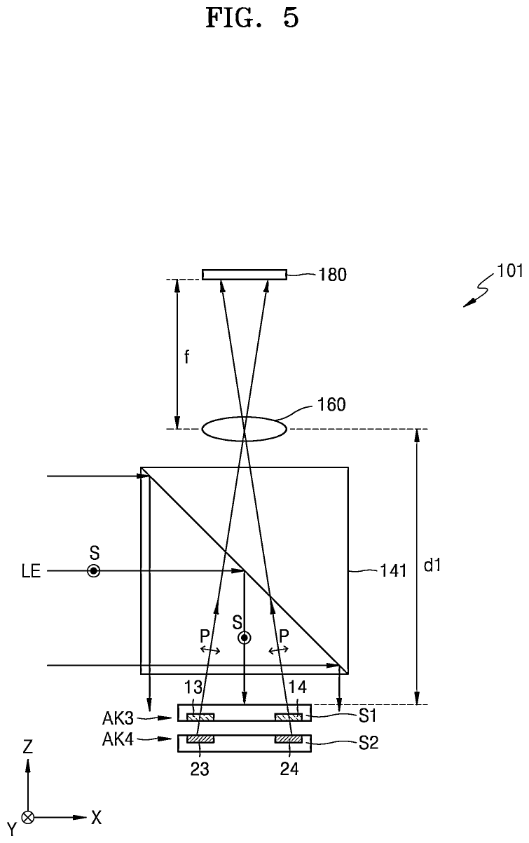

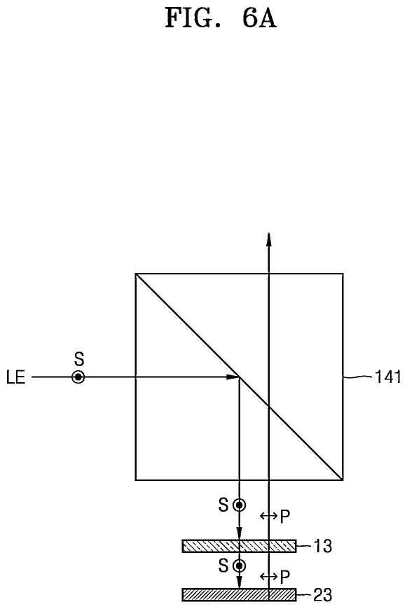

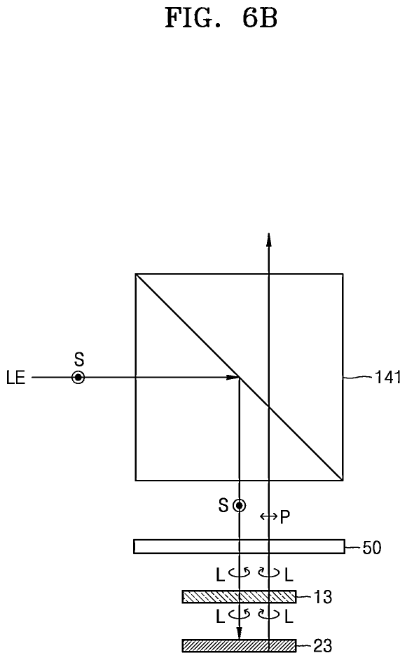

FIG. 5 illustrates a schematic structure of an optical measurement device according to another embodiment. FIGS. 6A and 6B illustrate examples of changes in polarization of light while light passes by a transmissive diffractive element and a reflective diffractive element provided in each of a first align mark and a second align mark of the optical measurement device of FIG. 5.

An optical measurement device 101 according to an embodiment of the present disclosure is different from the optical measurement device 100 of FIG. 1 in that the optical measurement device 101 includes a polarization beam splitter 141 for splitting incident light according to polarization, and a first align mark AK3 and a second align mark AK4 that are designed to be suitable for operation with respect to polarized light.

The polarization beam splitter 141 may exhibit different transmission and reflection effects for light of first polarization and second polarization which are different from each other. The first polarization and the second polarization may be linear polarization perpendicular to each other. The polarization beam splitter 141 may reflect light of a first polarization (e.g., S polarization), and transmit a second polarization perpendicular thereto (e.g., P polarization).

The first align mark AK3 and the second align mark AK4 are similar to the first align mark AK1 and the second align mark AK2 of FIG. 1, respectively, as the first align mark AK3 and the second align mark AK4 include a transmissive diffractive element and a reflective diffractive element, respectively. The first align mark AK3 and the second align mark AK4 are different from the first align mark AK1 and the second align mark AK2 in FIG. 1 in that a first transmissive diffractive element 13 and a second transmissive diffractive element 14, which form the first align mark AK3, and a first reflective diffractive element 23 and a second reflective diffractive element 33, which form the second align mark AK4, each include nanostructures, the shape and arrangement of which are determined to transmit or reflect S-polarized light.

When the incident light LE is S-polarized light, most of the incident light LE incident on the polarization beam splitter 141 is reflected and proceeds toward the first align mark AK3. After the incident light LE sequentially passes through the first transmissive diffractive element 13 of the first align mark AK3, is reflected by the first reflective diffractive element 23 of the second align mark AK4, passes through the first transmissive diffractive element 13 of the first align mark AK3, and is incident on the polarization beam splitter 141 again, the light may be in a P polarization state. As described above, most of the incident P-polarized light passes through the polarization beam splitter 141 and is directed to the focusing lens 160.

The light path described above is described as passing through the first transmissive diffractive element 13, reflecting from the first reflective diffractive element 23, and passing through the first transmissive diffractive element 13 again, but is not limited thereto. Light reflected from the polarization beam splitter 141 may re-enter the polarization beam splitter 141 after sequentially reflecting from the first reflective diffractive element 23 and passing through the first transmissive diffractive element 13, or may re-enter the polarization beam splitter 141 after sequentially passing through the first transmissive diffractive element 13 and reflecting from the first reflective diffractive element 23.

On these light paths, little light loss occurs due to the polarization beam splitter 141, which may be advantageous for sensing sensitivity in the image sensor 180. For example, in a case of the beam splitter 140 that is a half mirror, such as the optical measurement device 100 of FIG. 1, light loss by ½ occurs every time the light passes the beam splitter 140, and the amount of light that reaches the image sensor 180 is equal to or less than ¼ of the amount of light provided.

An example of a change in polarization while passing through the first align mark AK3, reflecting from the second align mark AK4, and re-passing through the first align mark AK3 is as follows with reference to FIGS. 6A and 6B.

Referring to FIG. 6A, the first transmissive diffractive element 13 and the first reflective diffractive element 23 may be designed to operate as a transmissive element and a reflective element, respectively, both for S-polarized light, and the change in polarization does not occur in the first transmissive diffractive element 13 and occurs only in the first reflective diffractive element 23.

The first transmissive diffractive element 13 may operate as a transmissive diffractive element such as, for example, a meta-lens or a meta-deflector for S-polarized light, and may be designed not to cause a change in polarization of the incident light occurs.

The first reflective diffractive element 23 may operate as a reflective element such as, for example, a meta-mirror or a meta-deflector, for S-polarized light, and may also be designed to reflect the light with changing the polarization of the incident light from S-polarization to P-polarization.

Referring to FIG. 6B, a ¼ wave plate 50 may be further arranged between the polarization beam splitter 141 and the first transmissive diffractive element 13. The ¼ wave plate 50 may convert incident S-polarized light into left-circularly polarized light L. The first transmissive diffractive element 13 and the first reflective diffractive element 23 may be designed to operate as a transmissive element or a reflective element, respectively, both for S-polarized light, and may be designed such that polarization conversion does not occur in the first transmissive diffractive element 13, but only in the first reflective diffractive element 23.

The first transmissive diffractive element 13 may operate as a transmissive diffractive element such as, for example, a meta-lens or a meta-deflector for left-circularly polarized light L, and may be designed not to convert the polarization of the incident light.

The first reflective diffractive element 23 may operate as a reflective element such as, for example, a meta-mirror or a meta-deflector for the incident left-circularly polarized light L, and may be designed to reflect the left-circularly polarized light L as the left-circularly polarized light L.

The light path described above is described as passing through the first transmissive diffractive element 13, reflecting from the first reflective diffractive element 23, and passing through the first transmissive diffractive element 13, but is not limited thereto. Light that is reflected from the polarization beam splitter 141 and has passed through the ¼ wave plate 50 may re-enter the ¼ wave plate 50 again after sequentially reflecting from the first reflective diffractive element 23 and passing through the first transmissive diffractive element 13, or may re-enter the ¼ wave plate 50 by sequentially passing through the first transmissive diffractive element 13 and reflecting from the first reflective diffractive element 23.

As described above, nanostructures having an asymmetric shape may be used for the first align mark AK3 and the second align mark AK4 that act on polarized light. At least one from among the first align mark AK3 and the second align mark AK4 may include a nanostructure having an asymmetric shape.

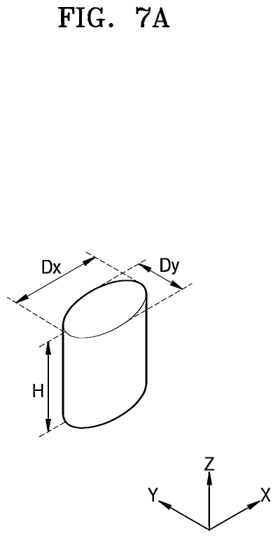

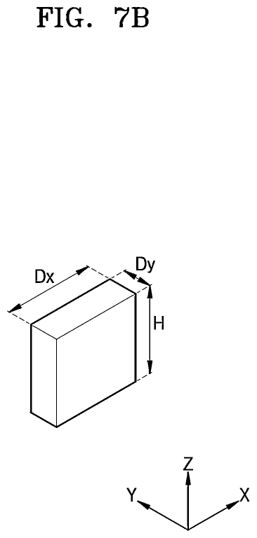

FIGS. 7A and 7B illustrate examples of shapes of nanostructures that may be respectively provided in first and second align marks of the optical measurement device of FIG. 5.

A cross-sectional shape of the nanostructures provided in the first align mark AK3 or the second align mark AK4 may have an asymmetry of 2-fold or more. The nanostructures may independently have a pillar shape with an asymmetric cross-section where a major axis and a minor axis are defined. For example, as illustrated in FIG. 7A, the nanostructures may have a cross-section of an elliptical pillar shape having a length Dx in a major axis direction and a length Dy in a minor axis direction, the length Dx and the length Dy being different from each other. Alternatively, the nanostructures may have a cross-section of a rectangular pillar shape having a length Dx in a major axis direction and a length Dy in a minor axis direction, the length Dx and the length Dy being different from each other.

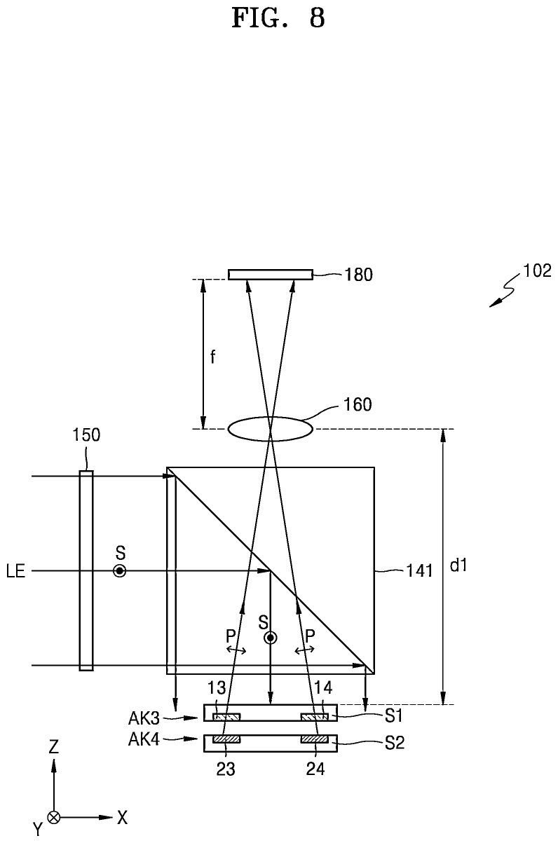

FIG. 8 illustrates a schematic structure of an optical measurement device according to an embodiment.

An optical measurement device 102 according to an embodiment of the present disclosure differs from the optical measurement device 101 of FIG. 5 in that a polarizer 150 is further provided to provide polarized light to the polarization beam splitter 141.

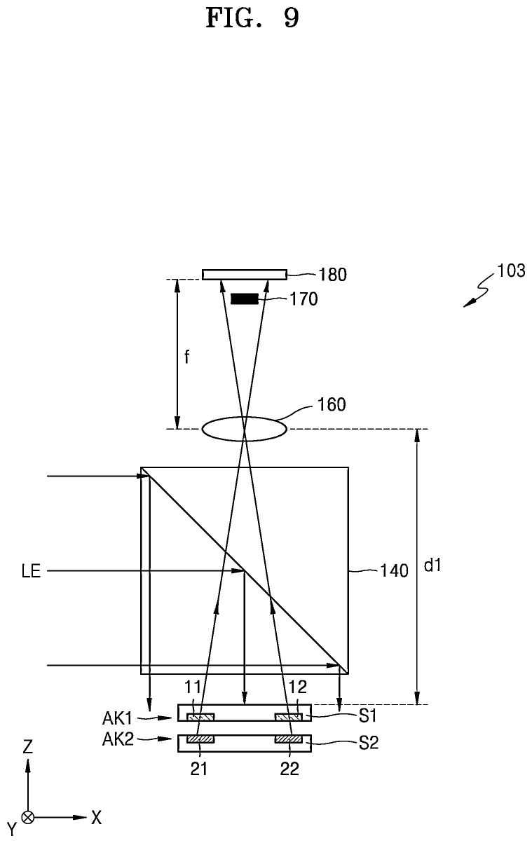

FIG. 9 illustrates a schematic structure of an optical measurement device according to an embodiment.

The optical measurement device 103 according to an embodiment of the present disclosure may include an aperture stop 170 that blocks a portion of the light incident on the image sensor 180. The aperture stop 170 includes an opening in the periphery thereof except a center thereof. For example, the aperture stop 170 may block some of light directed toward the center thereof among light incident on the image sensor 180.

An area where light is blocked by the aperture stop 170 may be an area at a position where beams from the first align mark AK1 and the second align mark AK2 are not focused. By blocking light from entering this area, saturation of a circuit during a photoelectric conversion operation of the image sensor 180 may be prevented.

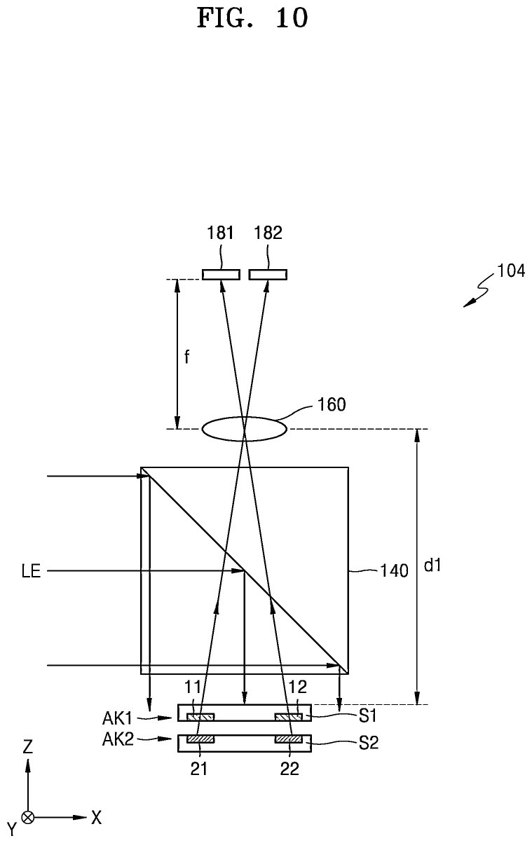

FIG. 10 illustrates a schematic structure of an optical measurement device according to an embodiment.

The optical measurement device 104 according to an embodiment of the present disclosure is different from the optical measurement device 100 of FIG. 1 in that the optical measurement device 104 includes two image sensors 181 and 182 arranged apart from each other.

Similar to the concept of including the aperture stop 170 in the optical measurement device 103 of FIG. 9, instead of using the aperture stop 170, the optical measurement device 104 includes two image sensors 181 and 182 arranged apart from each other in order that light directed to certain positions is not detected.

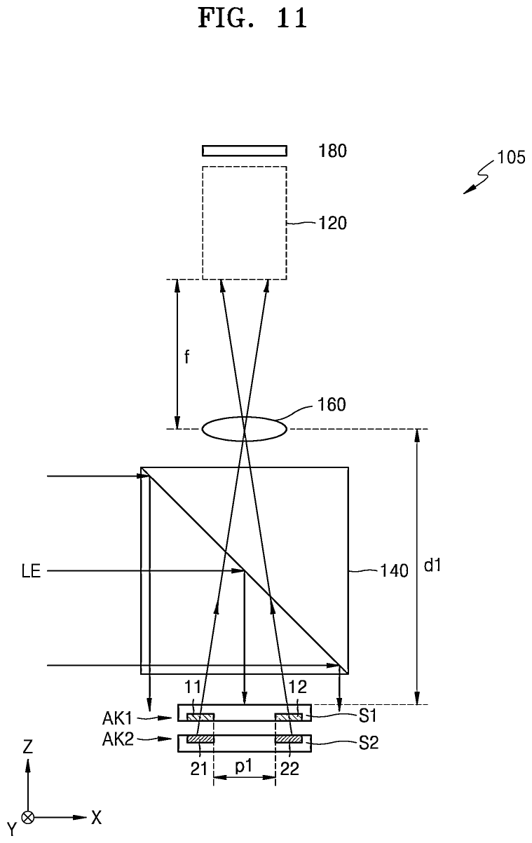

FIG. 11 illustrates a schematic structure of an optical measurement device according to an embodiment.

An optical measurement device 105 according to an embodiment of the present disclosure differs from the optical measurement device 100 of FIG. 1 in that a relay optical system 120 is further provided between the focusing lens 160 and the image sensor 180.

The relay optical system 120 may be arranged at a position of a focal distance f of the focusing lens 160 and may include, for example, a pair of relay lenses. The relay optical system 120 may provide an enlarged image to the image sensor 180.

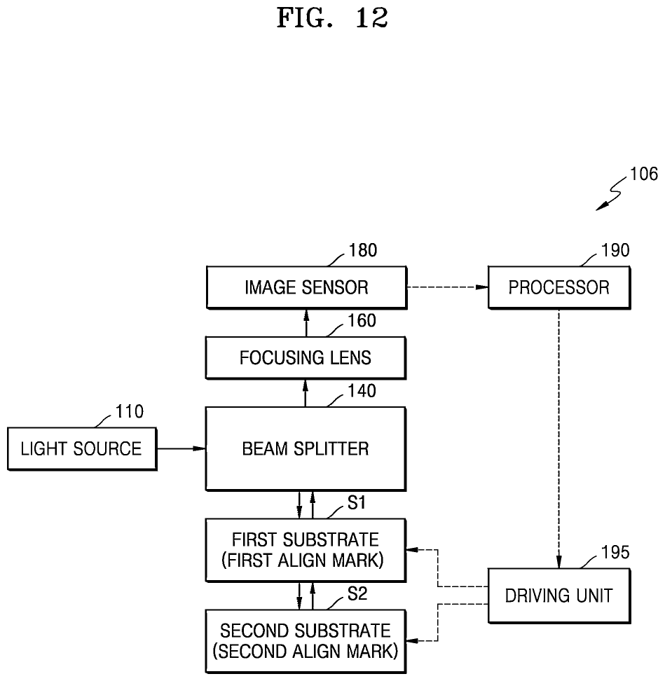

FIG. 12 illustrates a schematic structure of an optical measurement device according to an embodiment.

An optical measurement device 106 may include a light source 110, a beam splitter 140, a first substrate S1 including a first align mark, a second substrate S2 including a second align mark, a focusing lens 160, and an image sensor 180.

The light source 110 provides light to the beam splitter 140. A collimating lens may be further arranged between the light source 110 and the beam splitter 140 to provide collimated light to the beam splitter 140. Alternatively, this collimating lens may be included in the light source 110.

The image sensor 180 may detect a beam pattern that is formed after light from the light source 110 is reflected by the beam splitter 140 and passes through the first substrate S1, is reflected from the second substrate S2, and passes through the first substrate S1. For example, the beam pattern may be a beam pattern formed after light has passed through the first align mark AK1 of the first substrate S1, is reflected from the second align mark AK2 of the second substrate S2, and then passes through the first align mark AK1 of the first substrate S1 or a beam pattern formed after light has sequentially reflected from the second align mark AK2 of the second substrate S2 and passes through the first align mark AK1 of the first substrate S1, or a beam pattern formed after light has sequentially passed through the first align mark AK1 of the first substrate S1 and is reflected from the second align mark AK2 of the second substrate S2.

The optical measurement device 106 may further include a processor 190, and the processor 190 may analyze a degree of alignment between the first substrate S1 and the second substrate S2 according to a beam pattern sensed by the image sensor 180. That is, through comparison with a beam pattern that appears when the first substrate S1 and the second substrate S2 are properly aligned, whether the first substrate S1 and the second substrate S2 are aligned with each other or a degree of misalignment may be analyzed.

The processor 190 may also control the overall operation of the optical measurement device 106.

According to embodiments of the present disclosure, the processor 190 may include (or be provided with) memory storing computer code that is configured to, when executed by the processor 190, cause the processor 190 to perform its functions.

The optical measurement device 106 may further include a driving unit 195 (e.g., an actuator) and may move either the first substrate S1 or the second substrate S2 due to control by the processor 190. For example, one from among the first substrate S1 and the second substrate S2 may be fixed, and the other one may be arranged on a driving stage and the position thereof may be adjusted by the driving unit 195.

The optical measurement devices 103, 104, 105, and 106 of FIGS. 9 to 12 have a modified structure from the optical measurement device 100 of FIG. 1, but are an example. As with the optical measurement devices 101 and 102 of FIGS. 5 and 8, the modifications described above may be applied also when the first align mark AK3 and the second align mark AK4 including the polarization beam splitter 141 and designed in consideration of polarization.

The optical measurement devices described above have been described with reference to example embodiments illustrated in the drawings, but these are merely examples, and it will be understood to those skilled in the art that various modifications and other equivalent embodiments may be made therefrom without departing from the scope of the present disclosure. The described embodiments should be considered in a descriptive sense only and not for purposes of limitation.

By using the optical measurement device, alignment errors may be precisely measured during die bonding in various electronic device manufacturing processes.

The optical measurement devices described above may have almost no limitations in measuring alignment errors depending on the die size.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. An optical measurement device comprising:
a first align mark comprising at least one transmissive diffractive element;
a second align mark apart from the first align mark in a first direction and comprising at least one reflective diffractive element;
a beam splitter configured to reflect incident light in a direction toward the first align mark and transmit light from the first align mark;
a focusing lens on a path of the light that passes through the beam splitter; and
at least one image sensor configured to sense the light after the light passes through the focusing lens.

2. The optical measurement device of claim 1, wherein the at least one image sensor is at a position of a focal distance of the focusing lens.

3. The optical measurement device of claim 1, wherein the at least one transmissive diffractive element is a plurality of transmissive elements comprising a first transmissive diffractive element and a second transmissive diffractive element apart from each other in a second direction perpendicular to the first direction.

4. The optical measurement device of claim 3, wherein the at least one reflective diffractive element is a plurality of diffractive elements comprising:
a first reflective diffractive element apart from the first transmissive diffractive element in the first direction, and
a second reflective diffractive element apart from the second transmissive diffractive element in the first direction.

5. The optical measurement device of claim 1, wherein the at least one transmissive diffractive element comprises a meta-lens or a meta-deflector, and the meta-lens or the meta-deflector comprises a plurality of nanostructures.

6. The optical measurement device of claim 1, wherein the at least one reflective diffractive element comprises a meta-mirror or a meta-deflector, and the meta-mirror or the meta-deflector comprises a plurality of nanostructures.

7. The optical measurement device of claim 1, wherein the beam splitter comprises a half mirror.

8. The optical measurement device of claim 1, wherein the beam splitter comprises a polarization beam splitter that is configured to reflect light of a first polarization and transmit light of a second polarization perpendicular to the first polarization.

9. The optical measurement device of claim 8, wherein the at least one reflective diffractive element is configured to reflect the light having the first polarization, that is previously reflected from the polarization beam splitter, with the second polarization.

10. The optical measurement device of claim 8, further comprising a ¼ wave plate between the polarization beam splitter and the first align mark.

11. The optical measurement device of claim 8, wherein the at least one transmissive diffractive element and the at least one reflective diffractive element each comprise a plurality of nanostructures, and
a cross-sectional shape of at least some of the plurality of nanostructures, in a second direction perpendicular to the first direction, has an asymmetry of 2-fold or more.

12. The optical measurement device of claim 8, further comprising a polarizer at one side of the polarization beam splitter and configured to convert polarization of the incident light into the first polarization.

13. The optical measurement device of claim 1, further comprising an aperture stop between the at least one image sensor and the focusing lens, the aperture stop configured to block a portion of the light from being incident on the at least one image sensor.

14. The optical measurement device of claim 1, wherein the at least one image sensor is a plurality of image sensors comprising a first image sensor and a second image sensor that are apart from each other in a second direction perpendicular to the first direction.

15. The optical measurement device of claim 1, further comprising a relay optical system between the focusing lens and the at least one image sensor,
wherein the relay optical system is at a position of a focal distance of the focusing lens.

16. The optical measurement device of claim 1, further comprising a light source that is configured to provide light incident on the beam splitter.

17. The optical measurement device of claim 1, wherein the first align mark is on a first substrate, and
the second align mark is on a second substrate that is different from the first substrate.

18. The optical measurement device of claim 17, further comprising a processor that is configured to analyze an alignment state of the first substrate and the second substrate according to a beam pattern sensed by the at least one image sensor.

19. The optical measurement device of claim 18, further comprising an actuator configured to move at least one from among the first substrate and the second substrate according to control by the processor.

20. The optical measurement device of claim 1, wherein the at least one transmissive diffractive element and the at least one reflective diffractive element each comprise a plurality of nanostructures.
